(19) United States
(12) Patent Application Publication
(10) Pub. No.: US 2024/0405163 A1
(43) Pub. Date: Dec. 5, 2024

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: Bin JIANG, Xiamen (CN); Chung-Ying CHANG, Xiamen (CN); Jiming CAI, Xiamen (CN); Yashu ZANG, Xiamen (CN); Xiuli HUANG, Xiamen (CN)

(21) Appl. No.: 18/663,261

(22) Filed: May 14, 2024

(30) Foreign Application Priority Data
Jun. 5, 2023 (CN) 2023106576108

(51) Int. Cl. H01L 33/40

(52) U.S. Cl. CPC H01L 33/405; H01L 2933/0016

(57) ABSTRACT

A light-emitting diode and a light-emitting device are provided. A transparent conductive layer, a current blocking layer and a first metal reflective layer are sequentially arranged on a side of a second semiconductor layer away from an active layer. A side of the first metal reflective layer adjacent to the current blocking layer is a first Al reflective layer, and metal Al has high reflectivity in a short-wave band, increasing the reflection of light radiated by the active layer. Since there is no need to form an adhesion layer between the first Al reflective layer and the current blocking layer, there is no light absorption problem of the adhesion layer. A projection area of the first metal reflective layer is greater than or equal to that of the transparent conductive layer, so that the first metal reflective layer can cover a larger light-emitting surface, thereby further improving the light reflection.

### CROSS-REFERENCE TO RELATED APPLICATION

This application claims priority to Chinese patent application No. CN202310657610.8, filed to China National Intellectual Property Administration (CNIPA) on Jun. 5, 2023, which is herein incorporated by reference in its entirety.

### TECHNICAL FIELD

The disclosure relates to the field of semiconductor technologies, and more particularly to a light-emitting diode and a light-emitting device.

### BACKGROUND

Light-emitting diode (LED) has the advantages of high efficiency, long life, small size and low power consumption, and is widely used in fields such as indoor and outdoor white lighting, screen display, backlight and so on. The luminous efficiency of LED is one of the most important indicators to measure the quality of LED devices.

In the related art, for vertical chips, silver is mostly used as a reflective electrode to form a current blocking layer above a transparent conductive layer, and then an adhesion layer and a silver mirror are deposited above the current blocking layer. Although the silver mirror has a good reflection effect, the reflectivity of silver will drop sharply in a short-wave band (for example, about 365 nanometers abbreviated as nm), and because of the poor adhesion between silver and the current blocking layer, it is often necessary to add an adhesion layer between silver and the current blocking layer. However, the adhesion layer is generally made of indium tin oxide (ITO), and there is also a serious light absorption phenomenon in the short-wave band, which leads to the reduction of the luminous efficiency of the chip.

In view of this, it is necessary to provide a technology that can reduce the absorption of light and increase the reflection of light in the short-wave band, so as to further improve the light extraction efficiency (also referred to as light-emitting efficiency) of LED chips.

### SUMMARY

In view of the defects and deficiencies of LED chips in the related art, especially light-emitting diodes, the disclosure provides a light-emitting diode and a light-emitting device to further improve the light extraction efficiency of the LED chips.

In an aspect of the disclosure, a light-emitting diode is provided, which has a light-emitting surface and a back surface oppositely arranged. The light-emitting diode includes a semiconductor stacked layer, and the semiconductor stacked layer includes a first semiconductor layer, an active layer and a second semiconductor layer sequentially arranged in that order from the light-emitting surface to the back surface.

A transparent conductive layer, a current blocking layer and a first metal reflective layer are sequentially formed on a side of the second semiconductor layer facing away from the active layer. The current blocking layer defines first through holes penetrating through the current blocking layer to the transparent conductive layer, a second metal reflective layer is formed in the first through holes, and the first metal reflective layer is electrically connected to the transparent conductive layer through the second metal reflective layer. The first metal reflective layer includes a first aluminum (Al) reflective layer disposed adjacent to the current blocking layer.

In another aspect of the disclosure, a light-emitting device is provided, which includes a circuit substrate and light-emitting elements arranged above the circuit substrate. Each of the light-emitting elements includes the light-emitting diode, and the light-emitting diode is electrically connected to the circuit substrate through an electrode structure.

As mentioned above, the light-emitting diode and the light-emitting device of the disclosure have the following beneficial effects.

In the light-emitting diode of the disclosure, the transparent conductive layer, the current blocking layer and the first metal reflective layer are sequentially formed on the side of the second semiconductor layer facing away from the active layer, the side of the first metal reflective layer adjacent to the current blocking layer is the first Al reflective layer, and metal Al has high reflectivity in a short-wave band, so that the reflection of light radiated by the active layer can be increased. In this situation, since the first Al reflective layer and the current blocking layer have good adhesion, there is no need to form an adhesion layer between them, and there is no problem of light absorption by the adhesion layer.

In the disclosure, the first through holes are defined in the current blocking layer, and the second metal reflective layer is formed in the first through holes. The second metal reflective layer at least includes a metal adhesion layer formed in the first through holes and a second Al reflective layer formed above the metal adhesion layer. The metal Al also plays the role of reflection in the first through holes, increasing the reflection of light. In addition, the second metal reflective layer also fills the first through holes, so that the current blocking layer and the second metal reflective layer form a flat surface, which is beneficial to the subsequent formation of the first metal reflective layer into a flat structure and enhances its reflection effect.

As mentioned above, both the first metal reflective layer and the second metal reflective layer in the disclosure both adopt Al as the reflective layer and do not contain silver (Ag), so that the problem of Ag migration does not exist, and at the same time, a larger first metal reflective layer can be formed, so that the light reflection can be further improved, thereby improving the light-emitting efficiency of the chip.

The light-emitting device of the disclosure includes the light-emitting diode of the disclosure, so that the light-emitting device of the disclosure has better light-emitting effect and display effect.

### BRIEF DESCRIPTION OF DRAWINGS

FIG. 1 illustrates a schematic structural diagram showing a structure of an LED chip in the related art.

FIG. 2A illustrates a schematic structural diagram of a light-emitting diode according to an embodiment 1 of the disclosure.

FIG. 2B illustrates a schematic structural diagram of a top view of the light-emitting diode illustrated in FIG. 2A.

FIG. 2C illustrates a schematic partially enlarged structural view of a portion C in FIG. 2C.

FIG. 3 illustrates a schematic partially enlarged structural view of a portion A in FIG. 2C.

FIG. 4 illustrates a schematic partially enlarged structural view of a portion B in FIG. 2C.

FIG. 5 illustrates a schematic structural diagram of a light-emitting diode according to an embodiment 2 of the disclosure.

FIG. 6 illustrates a schematic structural diagram of a light-emitting diode according to an embodiment 3 of the disclosure.

FIG. 7 illustrates a schematic flowchart of a manufacturing method of a light-emitting diode according to an embodiment 4 of the disclosure.

FIGS. 8-13 illustrate schematic structural views of the light-emitting diode according to the embodiment 4 in different manufacturing stages.

FIG. 14 illustrates a diagram showing comparison of reflectivity of Ag and Al in different wave bands.

FIG. 15 illustrates a schematic structural diagram of a light-emitting device according to an embodiment 5 of the disclosure.

### DESCRIPTION OF REFERENCE NUMERALS

10, LED chip; 11, semiconductor stacked layer; 12, current blocking layer; 13, adhesion layer; 14, silver (Ag) mirror; 15. metal protective layer; 100, LED; 101, semiconductor stacked layer; 1010, second through hole; 1011, first semiconductor layer; 1012, active layer; 1013, second semiconductor layer; 102, transparent conductive layer; 103, current blocking layer; 1030, first through hole; 104, second metal reflective layer; 1041, metal adhesion layer; 1042, second Al reflective layer; 1043, second metal protective layer; 105, first metal reflective layer; 1051, first Al reflective layer; 1052, first metal protective layer; 106, insulation layer; 1060, third through hole; 1061, insulation protective layer; 107, first metal layer; 107′, metal connection layer; 1070, conductive column; 108, second metal layer; 109, substrate; 1014, first electrode; 110, light-emitting surface; 120, back surface; 130, second electrode; 200, growth substrate; 300, light-emitting device; 301, circuit substrate; 302, light-emitting element.

### DETAILED DESCRIPTION OF EMBODIMENTS

Embodiments of the disclosure are described below through specific examples, and those skilled in the art can easily understand other advantages and effects of the disclosure from the contents disclosed in this specification. The disclosure can also be implemented or applied by other different specific embodiments, and various details in this specification can be modified or changed based on different viewpoints and applications without departing from the spirit of the disclosure.

As illustrated in FIG. 1, in the related art, a vertically designed LED chip 10 includes a semiconductor stacked layer 11 and a current blocking layer 12 formed above the semiconductor stacked layer 11, and an Ag mirror 14 is usually formed above the current blocking layer 12 to reflect light radiated by an epitaxial structure. An adhesion layer 13 is formed in through holes of the current blocking layer 12 and on a surface of the current blocking layer 12. The adhesion layer 13 is generally made of ITO, so as to realize the adhesion and electrical conduction of metal Ag to a transparent conductive layer and prevent the diffusion of Ag ions. In addition, in order to prevent the migration of the Ag ions, a metal protective layer 15 covering the Ag mirror 14 is usually formed in the related art. Although the Ag mirror 14 has a good reflection effect, in the short-wave band (for example, about 365 nm), the reflectivity of Ag will drop sharply, and the adhesion layer 13 also has a serious light absorption phenomenon in the short-wave range, which leads to the reduction of the luminous efficiency of the chip. At the same time, in the related art, the Ag mirror 14 is usually formed in the through holes of the current blocking layer 12 and on the surface outside the through holes, which leads to the uneven surface of the Ag mirror 14 and seriously affects its reflection effect.

In view of the above defects, the disclosure provides a light-emitting diode and a light-emitting device, which solve the technical problems in the background. In some embodiments, the light-emitting diode has a light-emitting surface and a back surface oppositely arranged. The light-emitting diode includes a semiconductor stacked layer, and the semiconductor stacked layer includes a first semiconductor layer, an active layer and a second semiconductor layer sequentially arranged in that order from the light-emitting surface to the back surface.

A transparent conductive layer, a current blocking layer and a first metal reflective layer are sequentially formed on a side of the second semiconductor layer facing away from the active layer. The current blocking layer defines first through holes penetrating through the current blocking layer to the transparent conductive layer, a second metal reflective layer is formed in the first through holes, and the first metal reflective layer is electrically connected to the transparent conductive layer through the second metal reflective layer. The first metal reflective layer includes a first Al reflective layer adjacent to the current blocking layer. Metal Al has high reflectivity in short-wave band, which can increase the reflection of light radiated by the active layer. Meanwhile, since no adhesion layer is formed between the first Al reflective layer and the current blocking layer, there is no light absorption problem of the adhesion layer. In addition, the second metal reflective layer also fills the first through holes, so that the current blocking layer and the second metal reflective layer form a flat surface, which is beneficial to the subsequent formation of the first metal reflective layer into a flat structure and enhances its reflection effect.

In some embodiments, the first metal reflective layer further includes a first metal protective layer formed on a side of the first Al reflective layer facing away from the current blocking layer. The first protective metal layer can well protect the first Al reflective layer from oxidation, and ensure its reflection effect and its conductivity as an electrode.

In some embodiments, the second metal reflective layer includes a metal adhesion layer formed at least at bottoms of the first through holes and a second Al reflective layer formed at a side of the metal adhesion layer facing away from the transparent conductive layer, and the second Al reflective layer is filled in the current blocking layer and the metal adhesion layer. The thin film structure of the metal adhesion layer solves the possible peeling problem between the metal Al and the transparent conductive layer due to poor adhesion, and avoids the high contact resistance caused by the fact that the metal Al is not in direct contact with the transparent conductive layer. The metal Al also plays the role of reflection in the first through holes, increasing the reflection of light.

In some embodiments, the second metal reflective layer further includes a second metal protective layer formed on a side of the second Al reflective layer facing away from the transparent conductive layer. The second protective metal layer plays a role in protecting the second Al reflective layer from oxidation, while ensuring its reflective effect and its conductivity as an electrode.

In some embodiments, a thickness of the second metal reflective layer is equal to or less than a depth of most of the first through holes. In a specific embodiment, the thickness of the second metal reflective layer is equal to the depth of the first through hole. The second metal reflective layer formed in the first through holes also fills the first through holes, so that the current blocking layer and the second metal reflective layer form a flat surface, which is beneficial to the subsequent formation of the first metal reflective layer into a flat structure and enhances its reflection effect.

In some embodiments, an absolute value of the difference between the thickness of the second metal reflective layer and the depth of the first through hole is not greater than 390 micrometers (μm). That is, the second metal reflective layer can be flush with the current blocking layer around the first through holes, or slightly concave or protruding relative to the current blocking layer, but the distance of concave or protruding is not more than 390 μm, thereby ensuring that the second metal reflective layer is flush or nearly flush with the current blocking layer. This in turn facilitates that flat coverage of the first metal reflective layer and enhance its reflection effect.

In some embodiments, a thickness of the metal adhesion layer is in range of 0.1 nm-10 nm. The thickness of the metal adhesion layer ensures the adhesion effect of the metal Al and the transparent conductive layer at the bottoms of the first through holes, and at the same time, avoids the obvious light absorption phenomenon caused by metal adhesion on the surface of the current blocking layer outside the first through holes, and ensures the light-emitting effect.

In some embodiments, a proportion of projection areas of the first through holes on the first metal reflective layer is in a range of 10%-30% or 30%-60%. On the one hand, the proportion of projection areas of the first through holes can ensure that sufficient electrical connection structures are formed between the first metal reflective layer and the transparent conductive layer. On the other hand, the adhesion between the second Al reflective layer and the transparent conductive layer can be ensured. In addition, the proportion of projection areas of the first through holes can also ensure the sufficient contact area between the first Al reflective layer and the current blocking layer and ensure the adhesion between them.

In some embodiments, a width of a bottom of the first through hole is in a range of 1 μm to 20 μm. The limitation of the width of the bottom of the first through hole can ensure that a uniform metal adhesion layer is formed at the bottom of the first through hole, and the adhesion between the second Al reflective layer and the transparent conductive layer can be ensured, and at the same time, no obvious light absorption can be generated.

In some embodiments, the thickness of the second Al reflective layer is in a range of 50 nm to 500 nm. The thickness ensures the sufficient reflection effect of metal Al, and at the same time, it is beneficial to fill the first through holes to form a flat surface, which is beneficial to the flat coverage of the first metal reflective layer and enhance its reflection effect.

In some embodiments, a thickness of the first Al reflective layer is in a range of 50 nm to 500 nm. The thickness can ensure the sufficient reflectivity and conductivity of the first Al reflective layer.

In some embodiments, the transparent conductive layer at least covers a part of a surface of the second semiconductor layer, and the current blocking layer at least covers the transparent conductive layer and an exposed surface of the second semiconductor layer. The transparent conductive layer can improve the expansibility of current, and at the same time, because the transparent conductive layer is an insulation material layer, it can also protect the surface and sidewall of the semiconductor stacked layer.

In some embodiments, a projected area of the first metal reflective layer is greater than or equal to a projected area of the transparent conductive layer. The first metal reflective layer of the disclosure adopts Al as the reflective layer and does not contain Ag, so that the problem of Ag migration does not exist, and a larger first metal reflective layer can be formed, thereby ensuring that the first metal reflective layer can cover a larger light-emitting surface, and further improving the light reflection.

In some embodiments, a wavelength of light emitted from the semiconductor stacked layer is below 380 nm. The metal Al has high reflectivity in short-wave band, which can increase the reflection of light radiated by the active layer and improve the light-emitting effect of the light-emitting diode.

In some embodiments, a material of the metal adhesion layer includes at least one selected from the group consisting of chromium (Cr), titanium (Ti), and nickel (Ni). The above metal material can avoid the peeling problem between the metal Al and the transparent conductive layer due to poor adhesion, so as to ensure sufficient reflectivity of the Al reflective layer.

In some embodiments, the material of the current blocking layer includes a transparent insulation layer including at least one selected from the group consisting of silicon oxide (SiO₂), silicon nitride, silicon oxynitride, titanium oxide, and aluminum oxide. In a specific embodiment, the current blocking layer is SiO₂, which has good adhesion itself, so there is no need to set another adhesion layer between the first Al reflective layer and the current blocking layer, which can not only ensure the adhesion effect between them, but also avoid the light absorption problem of the adhesion layer. In this situation, the metal Al and the SiO₂ can also form a higher reflection effect, increase the reflection of light radiated by the active layer and enhance the light-emitting effect.

In some embodiments, materials of the first metal protective layer and the second metal protective layer include at least one selected from the group consisting of Cr, platinum (Pt), Ni, Ti, and gold (Au). It is ensured that the first Al reflective layer and the second Al reflective layer are not oxidized to ensure sufficient reflectivity.

In some embodiments, the semiconductor stacked layer defines a second through hole penetrating from a side of the back surface into the first semiconductor layer, and the current blocking layer covers a sidewall of the second through hole. The arrangement of the second through hole facilitates the subsequent formation of the first electrode electrically connected to the first semiconductor layer.

In some embodiments, the light-emitting diode further includes: an insulation layer, a first metal layer, and a substrate. The insulation layer is disposed at a side of the first metal reflective layer facing away from the current blocking layer, covers the first metal reflective layer and an exposed part of the current blocking layer, and is disposed on the sidewall of the second through hole. The first metal layer is disposed at the side of the first metal reflective layer facing away from the current blocking layer and covers the insulation layer and fills the second through hole. The substrate is disposed at the side of the first metal reflective layer facing away from the current blocking layer and is bonded to the first metal layer.

In some embodiments, the light-emitting diode further includes a second metal layer disposed on the side of the first metal reflective layer facing away from the current blocking layer, and the second metal layer is located between the insulation layer and the first metal reflective layer. In a specific embodiment, a projection area of the second metal layer is greater than a projection area of the first metal reflective layer, which plays a role in protecting the first Al reflective layer and is also convenient for the subsequent formation of a second electrode electrically connected to the second semiconductor layer through the second metal layer.

In some embodiments, the light-emitting diode further includes: a first electrode and a second electrode. The first electrode is electrically connected to the first semiconductor layer. The second electrode is electrically connected to the second semiconductor layer.

The disclosure also provides a light-emitting device, which includes a circuit substrate and light-emitting elements arranged above the circuit substrate. The light-emitting element includes any one of the light-emitting diodes, and the light-emitting diode is electrically connected to the circuit substrate through an electrode structure.

The technical solutions of the disclosure will be described clearly and completely by means of a variety of specific embodiments in conjunction with the accompanying drawings in the embodiments of the disclosure.

### Embodiment 1

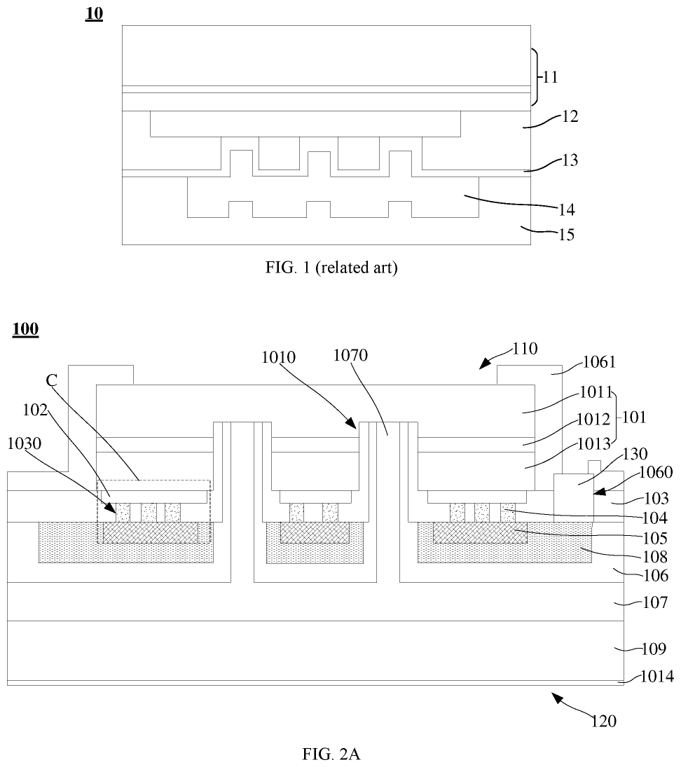

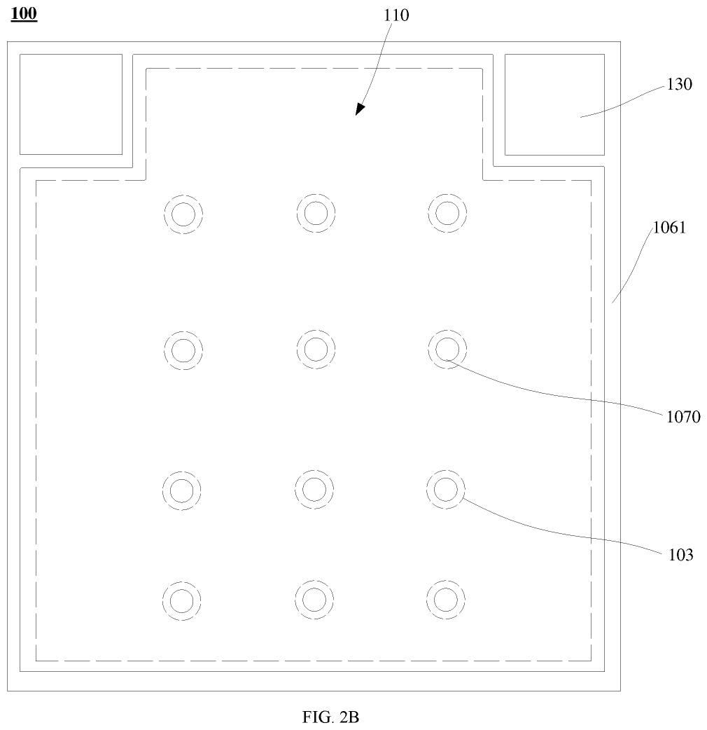

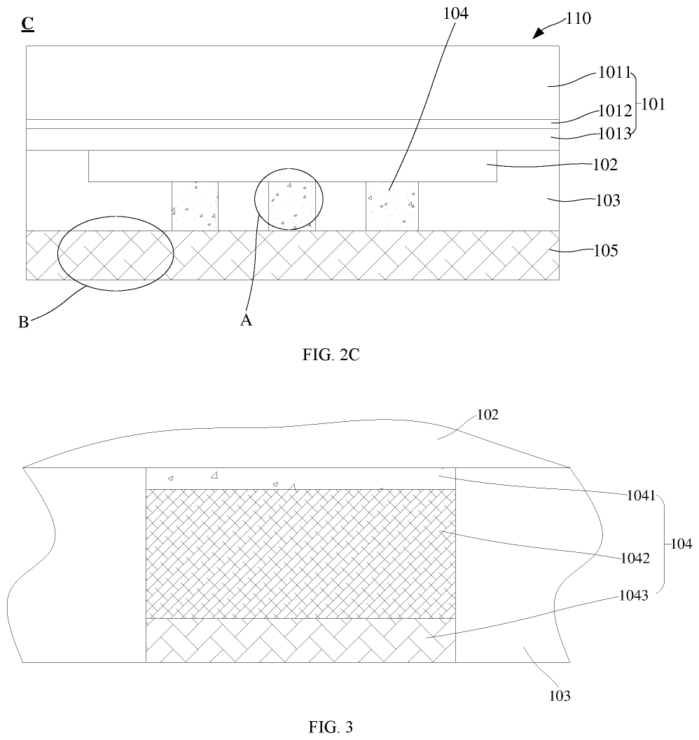

This embodiment provides a light-emitting diode, as illustrated in FIGS. 2A-2B. The light-emitting diode 100 includes a semiconductor stacked layer 101, and the light-emitting diode 100 has a light-emitting surface 110 and a back surface 120 opposite to the light-emitting surface 110. The semiconductor stacked layer 101 includes a first semiconductor layer 1011, an active layer 1012 and a second semiconductor layer 1013 sequentially arranged in that order from the light-emitting surface 110 to the back surface 120. As the light-emitting diode 100, it may be a gallium nitride (GaN)-based chip or a gallium arsenide (GaAs)-based chip. For example, the first semiconductor layer 1011 may be an N-type doped aluminum gallium nitride (AlGaN) layer, the second semiconductor layer 1013 may be a P-type doped AlGaN layer, and the active layer 1012 may be a multiple quantum well (MQW) composed of 5 to 15 cycles of AlGaN/indium gallium nitride (InGaN). A side of the first semiconductor layer 1011 facing away from the active layer 1012 is the light-emitting surface 110 of the light-emitting diode 100. In some embodiments, a wavelength range of the light emitted by the light-emitting diode 100 (that is, the light emitted by the semiconductor stacked layer 101) is in a range of 300 nm to 420 nm, that is, the light-emitting diode 100 is an ultraviolet light-emitting diode. In other embodiments, the wavelength of the light emitted from the semiconductor stacked layer 101 is below 380 nm. In a specific embodiment, the wavelength of the light emitted from the semiconductor stacked layer 101 is below 370 nm, for example, around 365 nm.

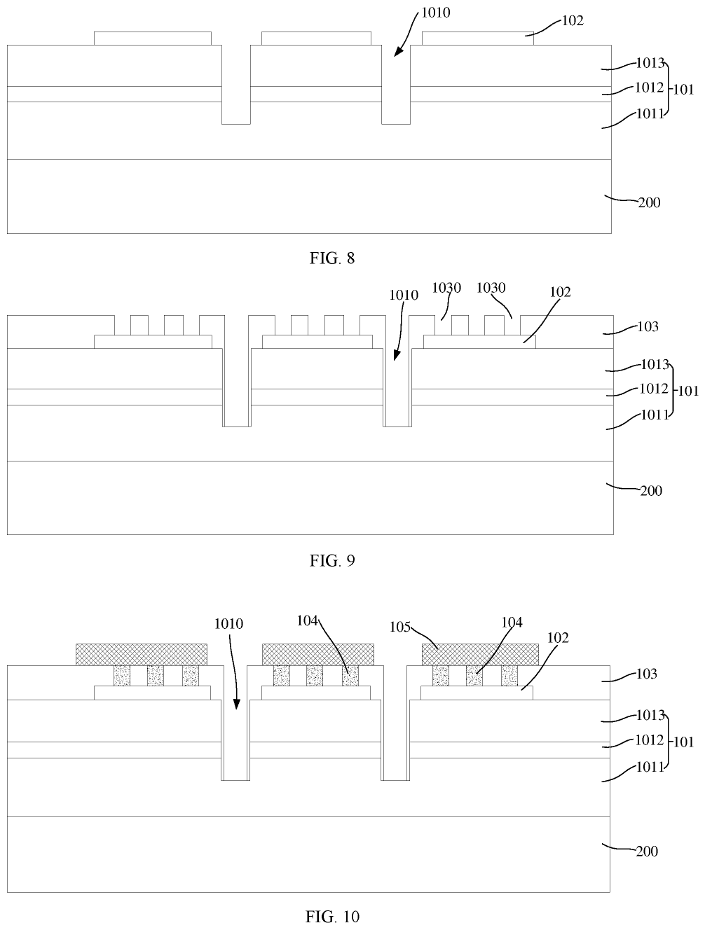

As illustrated in FIG. 2A and FIG. 2C, a transparent conductive layer 102, a current blocking layer 103 and a first metal reflective layer 105 are sequentially formed on a side of the second semiconductor layer 1013 facing away from the active layer 1012. The transparent conductive layer 102 can be ITO, aluminum doped zinc oxide (AZO), etc. The transparent conductive layer 102 at least covers a part of the surface of the second semiconductor layer 1013. In a specific embodiment, the transparent conductive layer 102 covers the entire surface of the second semiconductor layer 1013, so as to increase the contact area between a second electrode 130 and the second semiconductor layer 1013 and improve the expansibility of current. The current blocking layer 103 covers surfaces of the transparent conductive layer 102 and the exposed surface of the second semiconductor layer 1013. In a specific embodiment, the current blocking layer 103 can also cover other exposed surfaces and sidewalls of the semiconductor stacked layer 101. As illustrated in FIG. 2A, combined with FIGS. 8-9, at least one second through hole 1010 is defined in the semiconductor stacked layer 101 of the light-emitting diode 100, which penetrates the second semiconductor layer 1013 and the active layer 1012 from a side of the back surface 120, or continues to penetrate part of the first semiconductor layer 1011 and is formed in the first semiconductor layer 1011. The current blocking layer 103 covers the transparent conductive layer 102 above the second semiconductor layer 1013, wraps the sidewall of the transparent conductive layer 102, and covers the exposed surface of the second semiconductor layer 1013 and is formed on the sidewall of the second through hole 1010. In some embodiments, the material of the current blocking layer 103 is a transparent insulation layer, including at least one of transparent inorganic insulation materials such as silicon oxide, silicon nitride, silicon oxynitride, titanium oxide, or aluminum oxide, and in this embodiment, it is a SiO₂ layer.

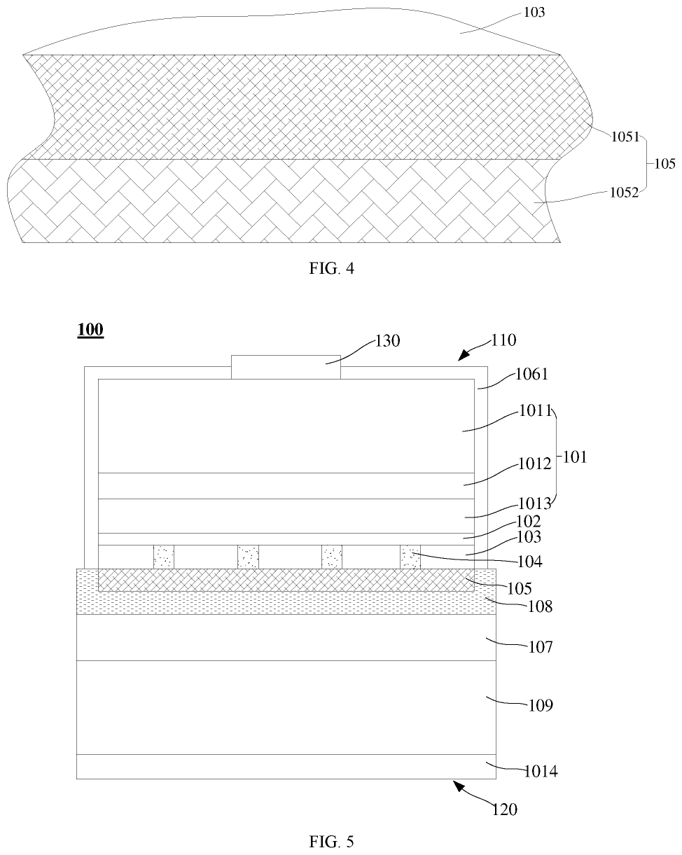

The first metal reflective layer 105 is formed above the current blocking layer 103, a projection of the first metal reflective layer 105 is located within the range of the second semiconductor layer 1013, and a projection area of the first metal reflective layer 105 is greater than or equal to a projection area of the transparent conductive layer 102, so as to cover all the light-emitting areas of the semiconductor stacked layer 101 as much as possible and reflect all the emitted light to a side of the light-emitting surface 110 as much as possible. In this embodiment, the first metal reflective layer 105 is formed in a multi-layer structure, which can be two or three or more layers. In a specific embodiment, the first metal reflective layer 105 is formed in a two-layer structure, as illustrated in FIG. 4, the first metal reflective layer 105 includes a first Al reflective layer 1051 and a first metal protective layer 1052. A side adjacent to the current blocking layer 103 is the first Al reflective layer 1051. As illustrated in FIG. 14, the reflectivity of Al is close to 90% in the short-wave range (about 365 nm), which is much higher than that of Ag. Therefore, by using Al as the mirror, the reflectivity in the short-wave range can be improved, and the light-emitting efficiency of the light-emitting diode 100 can be improved. In this embodiment, the first metal reflective layer 105 is made of Al and does not contain Ag ions, so there is no problem of Ag migration, and there is no need to form a protective layer to prevent Ag migration outside the first Al reflective layer 1051, thus saving the process steps and manufacturing costs, and at the same time, the area of the first Al reflective layer 1051 can be correspondingly increased to increase the reflection effect.

In an alternative embodiment, the first Al reflective layer 1051 is covered with the first metal protective layer 1052 above the first Al reflective layer 1051 to prevent the first Al reflective layer 1051 from being oxidized to affect its reflective effect and conductive effect. The first metal protective layer 1052 may be a single-layer or multi-layer structure of Cr, Ni, Ti, Au, Pt, etc. In another alternative embodiment, a thickness of the first Al reflective layer 1051 is in a range of 50 nm to 500 nm. In a specific embodiment, the thickness of the first Al reflective layer 1051 is above 150 nm. This thickness can ensure the sufficient reflectivity and conductivity of the first Al reflective layer 1051. The first metal reflective layer 105 does not contain an Ag layer, so the reflection efficiency in the short-wave range is improved, and the problem that the diffusion of Ag ions affects the luminous efficiency is also avoided. In addition, the metal Al and the SiO₂ forming the current blocking layer 103 have good adhesion, so it is not necessary to form an adhesion layer between the first Al reflective layer 1051 and the current blocking layer 103 to ensure the adhesion effect between them. In this situation, the metal Al and the SiO₂ can also form a good reflection effect and enhance the light-emitting effect.

In order to realize the electrical connection between the first metal reflective layer 105 and the second semiconductor layer 1013, first through holes 1030 (see FIG. 9) are defined in the current blocking layer 103, which penetrate through the current blocking layer 103 until the transparent conductive layer 102 is exposed. In some embodiments, the number of the first through holes 1030 satisfies that a proportion of projection areas of the first through holes 1030 on the first metal reflective layer 105 is in a range of 10%-30%, or 30%-60%. In a specific embodiment, the proportion of projection areas of the first through holes 1030 on the first metal reflective layer 105 is in a range of 10% to 30%, for example, about 25%. On the one hand, the above proportion of projection areas of the first through holes 1030 can ensure the formation of sufficient electrical connection structure between the first metal reflective layer 105 and the transparent conductive layer 102. On the other hand, the adhesion between the second Al reflective layer 1042 and the transparent conductive layer 102 can be ensured. In addition, the proportion of projection areas of the first through holes 1030 1030 can also ensure a sufficient contact area between the first Al reflective layer 1051 and the current blocking layer 103 and ensure the adhesion between them. A width of a bottom of the first through hole 1030 is in a range of 1 μm to 20 μm. In a specific embodiment, the width of the bottom of the first through hole 1030 is usually set to about 5 μm. The definition of the width of the bottom of the first through hole 1030 can ensure that the metal adhesion layer 1041 is formed at the bottom of the first through hole 1030 and can ensure the adhesion between the second Al reflective layer 1042 and the transparent conductive layer 102, and at the same time, no obvious light absorption can be generated. The second metal reflective layer 104 is formed in the first through holes 1030. In an alternative embodiment, the thickness of the second Al reflective layer 1042 is in a range of 50 nm to 500 nm. In a specific embodiment, the thickness of the second Al reflective layer 1042 is in a range of 100 nm to 200 nm. The second metal reflective layer 1041 is also formed in a multi-layer structure, which can be two or three or more layers. In an alternatively embodiment, as illustrated in FIG. 3, the second metal reflective layer 104 is formed in a multi-layer structure. For example, the second metal reflective layer 104 may include a metal adhesion layer 1041 formed at the bottom of the first through holes 1030 and a second Al reflective layer 1042 formed on a side of the metal adhesion layer 1041 facing away from the transparent conductive layer 102. The metal adhesion layer 1041 may be a single-layer or multi-layer structure of Cr, Ti, Ni, etc. The metal adhesion layer 1041 is a thin film structure with a thickness in a range of 0.1 nm to 10 nm. In a specific embodiment, the thickness of the metal adhesion layer 1041 is in a range of 1 nm to 3 nm. This thickness can ensure the adhesion effect with the transparent conductive layer 102 at the bottom of the through holes, and at the same time, the metal adhesion layer 1041 is not formed on the surface of the current blocking layer 103 outside the first through holes 1030, so there is no obvious light absorption phenomenon, and the light-emitting effect is ensured. The second Al reflective layer 1042 is formed inside the first through holes 1030, that is, filled inside the current blocking layer 103, and its surface is lower than or flush with open ends of the first through holes 1030. In a specific embodiment, the surface of the second Al reflective layer 1042 is flush with the open ends of the first through holes 1030. The thin film structure of the metal adhesion layer 1041 solves the peeling problem between the metal Al and the transparent conductive layer due to poor adhesion, and at the same time avoids the high contact resistance caused by the direct contact of the metal Al with the transparent conductive layer. The second Al reflective layer 1042 also reflects the light emitted from the semiconductor stacked layer 101, thus increasing the reflection effect. The current blocking layer 103 and the second metal reflective layer 104 are formed as a flat surface, which is beneficial to the subsequent formation of the first metal reflective layer 105 as a flat structure and enhances its reflection effect.

In other alternative embodiments, the metal adhesion layer 1041 may also be formed on the sidewalls of the first through holes 1030, and the second Al reflective layer 1042 is filled in the metal adhesion layer 1041.

In an alternative embodiment, as illustrated in FIG. 3, a second metal protective layer 1043 is further formed on a side of the second Al reflective layer 1042 facing away from the transparent conductive layer 102, and the second metal protective layer 1043 can also be a single-layer or multi-layer structure such as Au and Pt, so as to protect the second Al reflective layer 1042 from oxidation and ensure its reflective effect and conductive effect. At this time, the surface of the second Al reflective layer 1042 is lower than the opening ends of the first through holes 1030, and the surface of the second metal protective layer 1043 is flush with the current blocking layer 103 forming the first through holes 1030, thus ensuring that the current blocking layer 103 and the second metal protective layer 1043 form a flat surface, which ensures that the surface of the first metal reflective layer 105 formed on the current blocking layer 103 is flat and free from defects such as depressions, thus further improving its reflection effect.

Also as illustrated in FIG. 2A, an insulation layer 106, a first metal layer 107 and a substrate 109 are formed on a side of the first metal reflective layer 105 facing away from the current blocking layer 103, and the insulation layer 106 covers the first metal reflective layer 105 and the exposed current blocking layer 103. As illustrated in FIG. 12, the insulation layer 106 is also formed on the sidewalls of the second through holes 1010, that is, covering the current blocking layer 103 on the sidewalls of the second through holes 1010. The first metal layer 107 is formed over the insulation layer 106 and filled in the second through holes 1010 to be electrically connected to the first semiconductor layer 1011. The substrate 109 is bonded to the first metal layer 107. The substrate 109 may be a conductive substrate, an insulation substrate, or a semiconductor substrate or the like. When the substrate 109 is a conductive substrate, it may serve as a first electrode electrically connected to the first semiconductor layer 1011. In some embodiments, a conductive metal layer can also be deposited on the outside of the substrate 109 as the first electrode 1014. As illustrated in FIG. 2A, a second metal layer 108 is further formed on the side of the first metal reflective layer 105 facing away from the current blocking layer 103, which is located between the insulation layer 106 and the first metal reflective layer 105, and covers the first metal reflective layer 105, with a projected area greater than the first metal reflective layer 105. As illustrated in FIG. 2A, an insulation protective layer 1061 is formed above the light-emitting surface 110 of the light-emitting diode 100 and on the sidewall of the semiconductor stacked layer 101, and the insulation protective layer 1061 can also be formed above the current blocking layer 103 at a periphery of the second semiconductor layer 1013. The second electrode 130 is formed on a periphery of the semiconductor stacked layer 101, and penetrates through the insulation protective layer 1061 and the current blocking layer 103 from the side of the light-emitting surface 110. The second electrode 130 is electrically connected to the second metal layer 108, and further electrically connected to the second semiconductor layer 1013.

### Embodiment 2

This embodiment also provides a light-emitting diode, as illustrated in FIG. 5. The light-emitting diode 100 also has a vertical structure, and also includes a semiconductor stacked layer 101. The light-emitting diode 100 has a light-emitting surface 110 and a back surface 120 opposite to the light-emitting surface 110. The semiconductor stacked layer 101 includes a first semiconductor layer 1011, an active layer 1012 and a second semiconductor layer 1013 sequentially arranged in that order from the light-emitting surface 110 to the back surface 120. The similarities with the embodiment 1 will not be described in detail, but the differences are as follows.

As illustrated in FIG. 5, in this embodiment, the transparent conductive layer 102 covers the entire surface of the second semiconductor layer 1013 on the side of the back surface 120 of the light-emitting diode 100, and the current blocking layer 103 covers the transparent conductive layer 102. First through holes 1030 penetrating through the current blocking layer 103 until the transparent conductive layer 102 is exposed are also defined in the current blocking layer 103. The second metal reflective layer 104 is formed in the first through holes 1030, and the first metal reflective layer 105 is formed above the current blocking layer 103. In a specific embodiment, an area of the first metal reflective layer 105 is equal to or greater than a surface area of the semiconductor stacked layer 101. The second metal layer 108 is formed over and completely covers the first metal reflective layer 105. A first metal layer 107 is formed on a side of the second metal layer 108 facing away from the first metal reflective layer 105. In some embodiments, the first metal layer 107 covers the second metal layer 108 and its sidewall, that is, a surface area of the first metal layer 107 is greater than that of the second metal layer 108. After that, the substrate 109 is bonded on the side of the first metal layer 107. In some embodiments, a metal layer is formed outside the substrate 109 as the first electrode 1014 electrically connected to the second semiconductor layer 1013.

On the side of the light-emitting surface 110 of the light-emitting diode 100, a conductive metal layer is deposited under the first semiconductor layer 1011 to form a second electrode 130. Similarly, as illustrated in FIG. 5, an insulation protective layer 1061 is formed on the light-emitting surface 110 and sidewall of the light-emitting diode 100, and the second electrode 130 penetrates through the insulation protective layer 1061 and is electrically connected to the first semiconductor layer 1011.

In this embodiment, the side of the first metal reflective layer 105 adjacent to the current blocking layer 103 is also the first Al reflective layer 1051. The metal Al has a high reflectivity in the short-wave band, which can increase the reflection of the light radiated by the active layer 1012. Meanwhile, since an adhesion layer is not formed between the first Al reflective layer 1051 and the current blocking layer 103, there is no light absorption problem of the adhesion layer. Moreover, the projection area of the first metal reflective layer 105 is greater than or equal to the projection area of the transparent conductive layer 102, so that the first metal reflective layer 105 can cover a larger light-emitting surface 110, thereby further improving the light reflection. In addition, the arrangement of the second metal reflective layer 104 also has the effect of flattening the metal reflective layer and enhancing its reflectivity.

### Embodiment 3

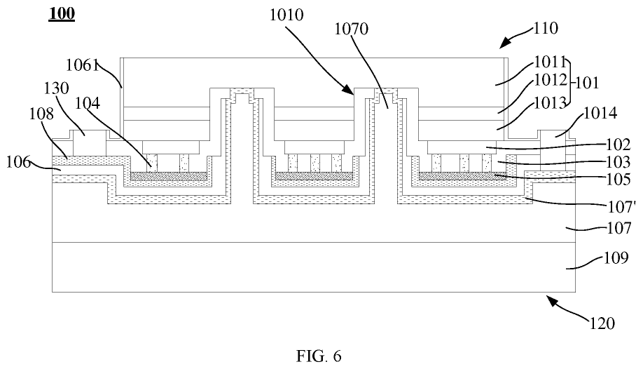

This embodiment also provides a light-emitting diode. As illustrated in FIG. 6, the light-emitting diode 100 also includes a semiconductor stacked layer 101, and the light-emitting diode 100 has a light-emitting surface 110 and a back surface 120 opposite to the light-emitting surface 110. The semiconductor stacked layer 101 includes a first semiconductor layer 1011, an active layer 1012 and a second semiconductor layer 1013 sequentially arranged in that order from the light-emitting surface 110 to the back surface 120. The similarities with the embodiment 1 and the embodiment 2 will not be described in detail, but the differences are as follows.

As illustrated in FIG. 6, in this embodiment, at least one second through hole 1010 is also defined in the semiconductor stacked layer 101 of the light-emitting diode 100, which penetrates the second semiconductor layer 1013 and the active layer 1012 from the side of the back surface 120, or continues to penetrate part of the first semiconductor layer 1011 and is formed in the first semiconductor layer 1011. The current blocking layer 103 covers the transparent conductive layer 102 above the second semiconductor layer 1013, wraps the sidewall of the transparent conductive layer 102, and covers the exposed second semiconductor layer 1013 and is formed on the sidewall of the second through hole 1010. The insulation layer 106 is also formed on the sidewall of the second through hole 1010. The difference is that a metal connection layer 107′ is also formed between the insulation layer 106 and the first metal layer 107, which covers the surface of the insulation layer 106 and is also formed on the surface of the insulation layer 106 on the sidewall of the second through hole 1010. The first metal layer 107 is formed on a surface of the metal connection layer 107′ and fills the second through hole 1010. A substrate 109 is bonded to the outside of the first metal layer 107, and the substrate 109 may be an insulation substrate or a semiconductor substrate.

An insulation protective layer 1061 is formed above the light-emitting surface 110 of the light-emitting diode 100 and on the sidewall of the semiconductor stacked layer 101. The insulation protective layer 1061 can also be formed above the transparent conductive layer 102 and the current blocking layer 103 at the periphery of the second semiconductor layer 1013. On the periphery of the semiconductor stacked layer 101, an electrode structure of the light-emitting diode 100 is formed. The first electrode 1014 penetrates the insulation protective layer 1061 and the current blocking layer 103 on a side of the semiconductor stacked layer 101, and is connected to the metal connection layer 107′ and the first metal layer 107 to realize the electrical connection with the first semiconductor layer 1011. The second electrode 130 penetrates through the insulation protective layer 1061 and the current blocking layer 103, is connected to the second metal layer 108, and then is electrically connected to the second semiconductor layer 1013. In this situation, a structure in which the first electrode 1014 and the second electrode 130 face the positive side is formed, which is beneficial to manufacturing isometric electrodes (also referred to as coplanar electrodes) and simplifying the process flow. At the same time, it is also convenient to design multiple series and/or parallel connections, it is beneficial to manufacturing multiple series and/or parallel structures on the same growth substrate, and is beneficial to using as a unit component designed to be a high-voltage structure.

### Embodiment 4

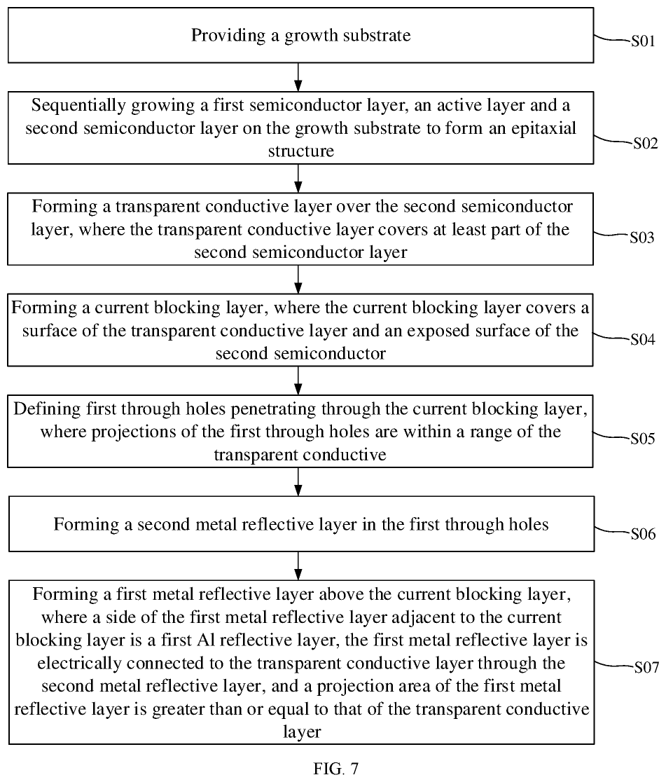

This embodiment provides a method for manufacturing a light-emitting diode. Taking the light-emitting diode of the embodiment 1 as an example, as illustrated in FIG. 7, the method includes the following steps.

S01: a growth substrate 200 is provided. As illustrated in FIG. 8, the growth substrate 200 may be a GaAs substrate or a sapphire substrate, and the sapphire substrate is taken as an example in this embodiment.

S02: a first semiconductor layer 1011, an active layer 1012 and a second semiconductor layer 1013 are sequentially grown on the growth substrate 200 to form a semiconductor stacked layer 101. As illustrated in FIG. 8, the semiconductor stacked layer 101 is a GaN-based epitaxial layer, in which the first semiconductor layer 1011 can be an N-type doped AlGaN layer, the second semiconductor layer 1013 can be a P-type doped AlGaN layer, and the active layer 1012 can be an MQW composed of 5 to 15 cycles of AlGaN/InGaN. Before growing the N-type doped AlGaN layer, a GaN layer can also be grown as a buffer layer.

After forming the semiconductor stacked layer 101, part of the semiconductor stacked layer 101 is etched from a side of the second semiconductor layer 1013 to form at least one second through hole 1010. Specifically, the second semiconductor layer 1013, the active layer 1012 and part of the first semiconductor layer 1011 are etched to form the second through hole 1010. After the formation of the second through hole 1010, the remaining semiconductor stacked layer 101 forms the light-emitting region of the light-emitting diode 100.

S03: a transparent conductive layer 102 is formed over the second semiconductor layer 1013, where the transparent conductive layer 102 covers at least part of the second semiconductor layer 1013.

As illustrated in FIG. 8, the transparent conductive layer 102 is formed over at least a part of the second semiconductor layer 1013. In some embodiments, for example, ITO or AZO is deposited on all surfaces of the second semiconductor layer 1013 in the light-emitting region to form the transparent conductive layer 102, and the transparent conductive layer 102 forms an ohmic contact with the second semiconductor layer 1013, which is beneficial to the expansion of current.

S04: a current blocking layer 103 is formed, where the current blocking layer 103 covers a surface of the transparent conductive layer 102 and an exposed surface of the second semiconductor layer 1013.

As illustrated in FIG. 9, the current blocking layer 103 is an insulation material layer. On the one hand, the current blocking layer 103 can block the current from diffusing below the P electrode (i.e., the second electrode 130 shown in FIG. 2A) and reduce the current density flowing to the active region below the P electrode metal, thus reducing the light loss caused by light absorption and light blocking by the P electrode metal. On the other hand, the current blocking layer 103, which is formed on both the surface and sidewall of the mesa structure, leads the current to a region facing away from the P electrode, thus reducing the current congestion near the P electrode and improving the light output power.

As illustrated in FIG. 9, the current blocking layer 103 is simultaneously formed on the sidewall of the second through hole 1010, which plays a role in protecting the semiconductor stacked layer 101 and insulating the semiconductor stacked layer 101.

S05: first through holes 1030 penetrating through the current blocking layer 103 are defined, where projections of the first through holes 1030 are within a range of the transparent conductive layer 102.

As illustrated in FIG. 9, after the formation of the current blocking layer 103, the first through holes 1030 are defined in the area where the current blocking layer 103 is located directly above the transparent conductive layer 102, and the number of the first through holes 1030 is not limited. In a specific embodiment, multiple of the first through holes are uniformly arranged in the above area.

S06: a second metal reflective layer 104 is formed in the first through holes 1030.

As illustrated in FIG. 10, in order to realize the subsequent electrical connection between the first metal reflective layer 105 and the transparent conductive layer 102 and simultaneously realize the partial reflection of the light radiated by the semiconductor stacked layer 101, the second metal reflective layer 104 is firstly formed in the first through holes 1030. In some embodiments, in order to ensure the adhesion between the second metal reflective layer 104 and the transparent conductive layer 102, the second metal reflective layer 104 is formed in a multi-layer structure. As illustrated in FIG. 3, firstly, a thin metal adhesion layer 1041 is deposited on sidewall and bottom of the first through hole 1030. The metal adhesion layer 1041 can be a single metal layer or a multi-layer metal layer formed of Cr, Ti, and Ni. A thickness of the metal adhesion layer 1041 is controlled to be 0.1 nm to 2.5 nm. Then Al is deposited over the metal adhesion layer 1041 to form a second Al reflective layer 1042, a surface of the second Al reflective layer 1042 is flush with an opening of the first through hole 1030, and the metal adhesion layer 1041 is below the second Al reflective layer 1042, thus solving the problem of poor adhesion between the second Al reflective layer 1042 and the transparent conductive layer 102.

In an alternative embodiment, one or more of Au, Pt, Ni, etc. can also be deposited over the second metal Al reflective layer 1042 to form a single-layer or multi-layer structure of a second metal protective layer 1043. At this time, the surface of the second metal Al reflective layer 1042 is made lower than the opening of the first through hole 1030. The second metal protective layer 1043 can effectively protect the second Al metal reflective layer 1042 from oxidation and ensure its reflective effect and conductive effect. Meanwhile, after the second metal protective layer 1043 is deposited, the second metal protective layer 1043 can be flatted so that its height is flush with the current blocking layer 103 outside the first through hole 1030.

S07: a first metal reflective layer 105 is formed above the current blocking layer 103. A side of the first metal reflective layer 105 adjacent to the current blocking layer 103 is a first Al reflective layer 1051. The first metal reflective layer 105 is electrically connected to the transparent conductive layer 102 through the second metal reflective layer 104, and a projection area of the first metal reflective layer 105 is greater than or equal to that of the transparent conductive layer 102.

As illustrated in FIG. 10, a metal material is deposited over the transparent conductive layer 102 to form the first metal reflective layer 105. Referring to FIG. 4, firstly, metal Al is deposited over the current blocking layer 103 to form the first Al reflective layer 1051, and the thickness of the first Al reflective layer 1051 is controlled to be greater than 5 nm. In some embodiments, the thickness of the first Al reflective layer 1051 is in a range of 100 nm to 500 nm. This thickness can ensure the reflective effect of the first Al reflective layer 1051, while also ensuring its conductive effect. Then, one or more of Au, Pt, Ni, etc. are deposited over the first metal Al reflective layer 1051 to form a single-layer or multi-layer first metal protective layer 1052. The first metal protective layer 1052 can effectively protect the first Al metal reflective layer 1051 from oxidation and ensure its reflective effect and conductive effect. In addition, as mentioned in the step S06 above, the height of the second metal protective layer 1043 is flush with the current blocking layer 103 outside the first through hole 1030, so the first Al reflective layer 1051 has a flat deposition surface, and the obtained first Al reflective layer 1051 and the first metal protective layer 1052 are both flat structures, which can also improve their reflection effect and increase the light-emitting effect of the LED chip.

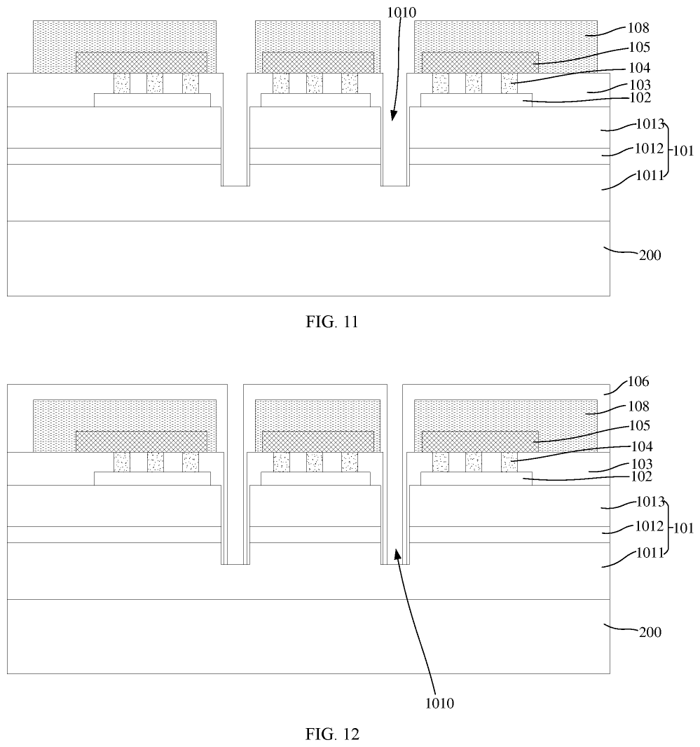

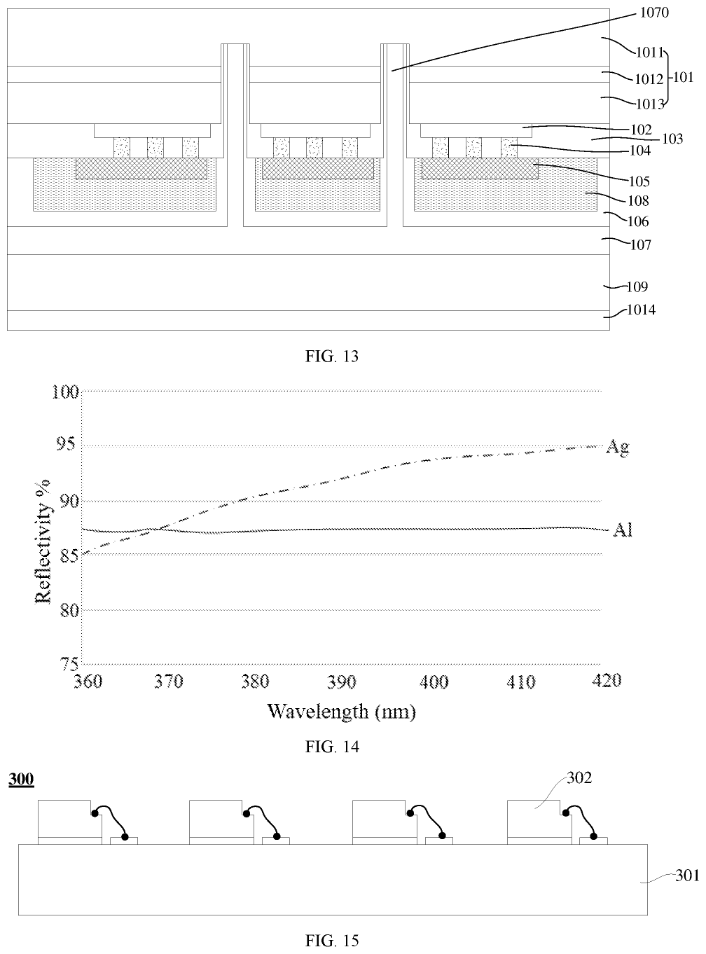

As illustrated in FIGS. 12-13, after the formation of the first metal reflective layer 105, there is a step of forming an insulation layer 106 and a first metal layer 107 above the first metal reflective layer 105. It can be understood that in order to facilitate the subsequent formation of the second electrode 130, as illustrated in FIG. 11, before forming the insulation layer 106, a second metal layer 108 is first formed above the first metal reflective layer 105, and the second metal layer 108 may be a metal layer such as Au or Pt. The second metal layer 108 covers the first metal reflective layer 105 and the current blocking layer 103 above the second semiconductor layer 1013 uncovered by the first metal reflective layer 105.

Then, as illustrated in FIG. 12, the insulation layer 106 is deposited over the semiconductor structure where the second metal layer 108 is formed, and the insulation layer 106 is formed on the sidewall of the second through hole 1010, that is, covers the current blocking layer 103 on the sidewall of the second through hole 1010. The insulation layer 106 may be a SiO₂ and/or SiN layer. In a specific embodiment, the insulation layer 106 is a SiO₂ layer. After the insulation layer 106 is formed, a metal material is deposited over the insulation layer 106 to form the first metal layer 107, and at the same time, the first metal layer 107 is deposited in the second through hole 1010 to form a conductive column 1070.

As illustrated in FIG. 13, after the formation of the first metal layer 107, the semiconductor structure is inverted and bonded to the substrate 109 through the first metal layer 107. The substrate 109 can be a metal substrate, a semiconductor substrate, or an insulation substrate. When the substrate 109 is a metal substrate, the substrate 109 can be used as the first electrode of the light-emitting diode 100. When the substrate 109 is a semiconductor substrate or an insulation substrate, a metal may be deposited on the side of the substrate 109 facing away from the first metal layer 107 to form the first electrode 1014.

After the above structure is formed, the growth substrate 200 is stripped off. Then, referring to FIG. 2A, the semiconductor stacked layer 101 is etched from the side of the first semiconductor layer 1011 in the edge region of the semiconductor stacked layer 101 until the current blocking layer 103 is exposed, and then an insulation protective layer 1061 is deposited on the etched surface, which covers the exposed current blocking layer 103 and the sidewall of the semiconductor stacked layer 101, or simultaneously covers the edge region of the surface of the first semiconductor layer 1011. Then, the insulation protective layer 1061 and the current blocking layer 103 are etched until the second metal layer 108 is exposed to form a third through hole 1060, and then metal is deposited in the third through hole 1060 to form the second electrode 130.

### Embodiment 5

This embodiment provides a light-emitting device. As illustrated in FIG. 15, the light-emitting device 300 includes a circuit substrate 301 and light-emitting elements 302 arranged above the circuit substrate 301. The light-emitting element 302 can be any one or more light-emitting diodes provided in the embodiments 1 to 4 of the disclosure. The light-emitting diode has good light-emitting efficiency, so the light-emitting device 300 also has good light-emitting effect.

The above-mentioned embodiments only illustrate the principle and efficacy of the disclosure, and are not used to limit the disclosure. Any person skilled in the art can modify or change the above embodiments without departing from the spirit and scope of the disclosure. Accordingly, it is intended that all such equivalent modifications and variations made by those skilled in the art without departing from the spirit and scope of the disclosure shall be covered by the appended claims of the disclosure.

What is claimed is:

1. A light-emitting diode, having a light-emitting surface and a back surface arranged oppositely, comprising:
a semiconductor stacked layer, wherein the semiconductor stacked layer comprises a first semiconductor layer, an active layer and a second semiconductor layer sequentially arranged in that order from the light-emitting surface to the back surface;
wherein a transparent conductive layer, a current blocking layer and a first metal reflective layer are sequentially formed on a side of the second semiconductor layer facing away from the active layer, the current blocking layer defines first through holes penetrating through the current blocking layer to the transparent conductive layer, a second metal reflective layer is formed in the first through holes, and the first metal reflective layer is electrically connected to the transparent conductive layer through the second metal reflective layer; and the first metal reflective layer comprises: a first aluminum (Al) reflective layer disposed adjacent to the current blocking layer.

2. The light-emitting diode as claimed in claim 1, wherein the first metal reflective layer further comprises a first metal protective layer formed on a side of the first Al reflective layer facing away from the current blocking layer.

3. The light-emitting diode as claimed in claim 1, wherein the second metal reflective layer comprises a metal adhesion layer formed at least at bottoms of the first through holes and a second Al reflective layer formed on a side of the metal adhesion layer facing away from the transparent conductive layer, and the second Al reflective layer is filled in the first through holes.

4. The light-emitting diode as claimed in claim 1, wherein the second metal reflective layer comprises:
a metal adhesion layer, formed on the transparent conductive layer, the metal adhesion layer being located in the first through holes;
a second Al reflective layer, formed on a side of the metal adhesion layer facing away from the transparent conductive layer, the second Al reflective layer being located in the first through holes; and
a second metal protective layer, formed on a side of the second Al reflective layer facing away from the transparent conductive layer, and the second metal protective layer being located in the first through holes.

5. The light-emitting diode as claimed in claim 1, wherein a thickness of the second metal reflective layer is equal to or less than a depth of each first through hole, and an absolute value of a difference between the thickness of the second metal reflective layer and the depth of each first through hole is not greater than 390 micrometers (μm).

6. The light-emitting diode as claimed in claim 3, wherein a thickness of the metal adhesion layer is in a range of 0.1 nanometers (nm) to 10 nm.

7. The light-emitting diode as claimed in claim 1, wherein a proportion of projection areas of the first through holes on the first metal reflective layer is in a range of 10%-30% or 30%-60%.

8. The light-emitting diode as claimed in claim 1, wherein a width of a bottom of each first through hole is in a range of 1 μm to 20 μm.

9. The light-emitting diode as claimed in claim 3, wherein a thickness of the second Al reflective layer is in a range of 50 nm to 500 nm.

10. The light-emitting diode as claimed in claim 1, wherein a thickness of the first Al reflective layer is in a range of 50 nm to 500 nm.

11. The light-emitting diode as claimed in claim 1, wherein the transparent conductive layer at least covers a part of a surface of the second semiconductor layer, and the current blocking layer at least covers the transparent conductive layer and an exposed surface of the second semiconductor layer.

12. The light-emitting diode as claimed in claim 1, wherein a projection area of the first metal reflective layer is greater than or equal to a projection area of the transparent conductive layer.

13. The light-emitting diode as claimed in claim 1, wherein a wavelength of light emitted from the semiconductor stacked layer is below 380 nm.

14. The light-emitting diode as claimed in claim 3, wherein a material of the metal adhesion layer comprises at least one selected from the group consisting of chromium (Cr), titanium (Ti), and nickel (Ni).

15. The light-emitting diode as claimed in claim 2, wherein the current blocking layer is a transparent insulation layer, and a material of the current blocking layer comprises at least one selected from the group consisting of silicon oxide, silicon nitride, silicon oxynitride, titanium oxide, and aluminum oxide; and
a material of the first metal protective layer comprises at least one selected from the group consisting of Cr, platinum (Pt), Ni, Ti, and gold (Au).

16. The light-emitting diode as claimed in claim 4, wherein a material of the second metal protective layer comprises at least one selected from the group consisting of Cr, Pt, Ni, Ti, and Au.

17. The light-emitting diode as claimed in claim 11, wherein the semiconductor stacked layer defines a second through hole penetrating from the back surface into the first semiconductor layer, and the current blocking layer covers a sidewall of the second through hole.

18. The light-emitting diode as claimed in claim 17, wherein the light-emitting diode further comprises:
an insulation layer, disposed at a side of the first metal reflective layer facing away from the current blocking layer, covering the first metal reflective layer and an exposed part of the current blocking layer, and disposed on the sidewall of the second through hole;
a first metal layer, disposed at the side of the first metal reflective layer facing away from the current blocking layer, and covering the insulation layer and filling the second through hole;
a substrate, disposed at the side of the first metal reflective layer facing away from the current blocking layer, and bonded to the first metal layer;
a first electrode, disposed at the side of the first metal reflective layer facing away from the current blocking layer, and electrically connected to the first semiconductor layer; and
a second electrode, disposed at the side of the first metal reflective layer facing away from the current blocking layer, and electrically connected to the second semiconductor layer.

19. The light-emitting diode as claimed in claim 18, wherein the light-emitting diode further comprises: a second metal layer, disposed on the side of the first metal reflective layer facing away from the current blocking layer, and the second metal layer is located between the insulation layer and the first metal reflective layer.

20. A light-emitting device, comprising: a circuit substrate and light-emitting elements arranged above the circuit substrate, wherein each of the light-emitting elements comprises the light-emitting diode as claimed in claim 1, and the light-emitting diode is electrically connected to the circuit substrate through an electrode structure.
